(19) United States
(12) Patent Application Publication
(10) Pub. No.: US 2008/0093744 A1
(43) Pub. Date: Apr. 24, 2008

(54) Anodization

(76) Inventors: Lorraine C. Wang, Corvallis, OR (US); Kurt Ulmer, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/585,431

(22) Filed: Oct. 23, 2006

(51) Int. Cl. H01L 23/52

(52) U.S. Cl. 257/758

(57) ABSTRACT

Embodiments of anodization are disclosed.

### CROSS-REFERENCE TO RELATED APPLICATION

This application is related to co-pending and commonly assigned application Ser. No. 10/961,507, filed Oct. 7, 2004 (attorney docket no. 200405644-1), the entire disclosure of which is incorporated herein by reference.

### BACKGROUND

Selective anodization of a metal has been accomplished by patterning a photoresist layer over the metal and anodizing portions of the metal not covered by the photoresist layer. However, in using this technique, there can be difficulty in forming the desired metal structures.

### BRIEF DESCRIPTION OF THE DRAWINGS

The features and advantages of the disclosure will readily be appreciated by persons skilled in the art from the following detailed description when read in conjunction with the drawings, wherein:

FIGS. 1-4 are cross-sectional side elevation views of embodiments of patterned metal structures at various stages of manufacture.

FIG. 5 is a flow chart schematically depicting an embodiment of a method using anodization in preparation of embodiments of patterned metal structures.

FIGS. 6 and 7 are cross-sectional side elevation views of an embodiment of patterned metal structures at two stages of manufacture.

FIGS. 8 and 9 are cross-sectional side elevation views of an embodiment of patterned metal structures at two stages of manufacture.

### DETAILED DESCRIPTION OF EMBODIMENTS

For clarity of the description, the drawings are not drawn to a uniform scale. In particular, vertical and horizontal scales may differ from each other and may vary from one drawing to another. In this regard, directional terminology, such as “top,” “bottom,” “front,” “back,” “leading,” “trailing,” etc., is used with reference to the orientation of the drawing figure(s) being described. Because components of the embodiments can be positioned in a number of different orientations, the directional terminology is used for purposes of illustration and is in no way limiting.

One embodiment includes a method for making a patterned metal structure. In such a method embodiment, the patterned metal structure is made by depositing a first thickness of a first metal on a substrate, depositing a second thickness of a second metal over the first metal, patterning the second metal by removing portions of the second metal from selected areas while leaving a continuous layer of the first metal, and anodizing the first and second metals until the first thickness of the first metal is at least substantially replaced by an oxide of the first metal under the selected areas (i.e., except where the first metal is covered by the second metal), and until the patterned second metal is covered by a layer of an oxide of the second metal.

For many applications, such as semiconductor integrated circuits, it is desirable that there be no conductive leakage path remaining between distinct portions of the patterned second metal after the anodization. For those applications in particular, it is desirable that the replacement of the first metal by its non-conductive oxide be complete wherever the first metal is not covered by the second metal. However, the replacement of the first metal by its non-conductive oxide does not necessarily need to be complete at an atomic level. For example, isolated atoms or isolated portions of the first metal may remain un-anodized for some applications.

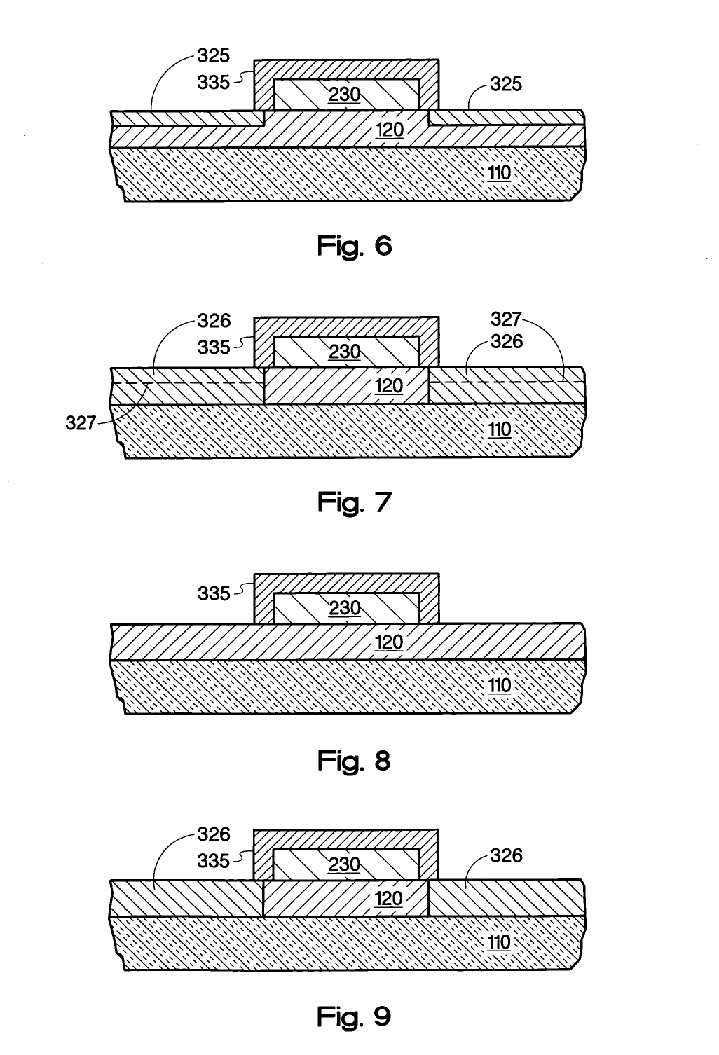

Anodization of the two metals is conveniently done substantially simultaneously for some embodiments, i.e., anodizing the first metal and the second metal during at least partially overlapping time intervals. The starting and ending times for the anodizing of the first and the second metals do not necessarily have to occur at exactly the same time. Other embodiments not utilizing simultaneous anodization are described below with reference to FIGS. 6-9.

The first and second metals are both anodizable metals under substantially the same anodization conditions for some embodiments. To characterize a metal as anodizable means that an oxide can be formed electrolytically on the surface of the metal and that the oxide growth rate for that metal under the anodization conditions is significantly faster than the oxide etch rate for that metal under the same conditions. The anodizable metal layers may each comprise any anodizable metal, but in order to provide for substantially simultaneous anodization, anodizable metals for such embodiments are chosen such that both anodize in the same anodization bath chemistry and at the same current/voltage conditions.

Anodization is a process of forming an oxide layer on a metal by making the metal the anode in an electrolytic cell and passing an electric current through the cell. For aluminum, for example, current density during anodization can range from about 0.1 milliamperes/cm² to 10 milliamperes/cm² or more depending upon the film properties desired. For anodization, the cell may contain, for example, an aqueous solution of an acid, such as phosphoric, citric, boric, tartaric, sulfuric, chromic, or oxalic acid. The cell may also contain, for example, a neutral solution such as ammonium borate or phosphate. Aluminum, tantalum, tungsten, and titanium are metals commonly anodized in such an anodization process. Many other metals, such as gallium, indium, tin, thallium, niobium, vanadium, molybdenum, zirconium, hafnium, and mixtures and alloys of these metals may also be anodized.

In the anodization process used in the embodiments described herein, the anodization rates of the two metals may be different or they may be the same. If the anodization rates of the two metals are different, either the first-deposited metal or the second-deposited metal may anodize faster than the other, but if the two anodization rates are both known prior to metal deposition, the desired deposition thicknesses may be properly determined.

The desired deposition thickness of the second-deposited (top layer) metal is determined by the desired oxide thickness and by the desired elemental metal thickness left over after anodization, taking into account that some of the metal is consumed during oxide growth.

The desired deposition thickness of the first-deposited (bottom layer) metal is directly dependent on the relative anodization rates of the two metals. With the desired deposition thickness of the first-deposited metal, when the entire thickness of the first-deposited (bottom layer) metal is consumed (in the selected areas where second-deposited metal was removed), the oxide covering the second-deposited (top layer) metal will be the desired target oxide thickness. Thus, those skilled in the art of anodization will recognize that the desired deposition thickness of the first-deposited (bottom layer) metal may be readily calculated, using the known relative anodization rates of the two metals.

Except for the features just described, the thicknesses may, in general, vary provided the first deposited metal has low sheet resistivity and is a continuous film that coats over any surface defects of its substrate, and that the second deposited metal has sufficient excess thickness to allow for partial consumption (oxidation) of the metal film during the anodization process used. A suitable thickness of aluminum, for example, is 200 nanometers to 500 nanometers on a sufficiently smooth defect-free layer of the first-deposited metal (e.g., tantalum), of suitable thickness according to the two relative anodization rates, as described above.

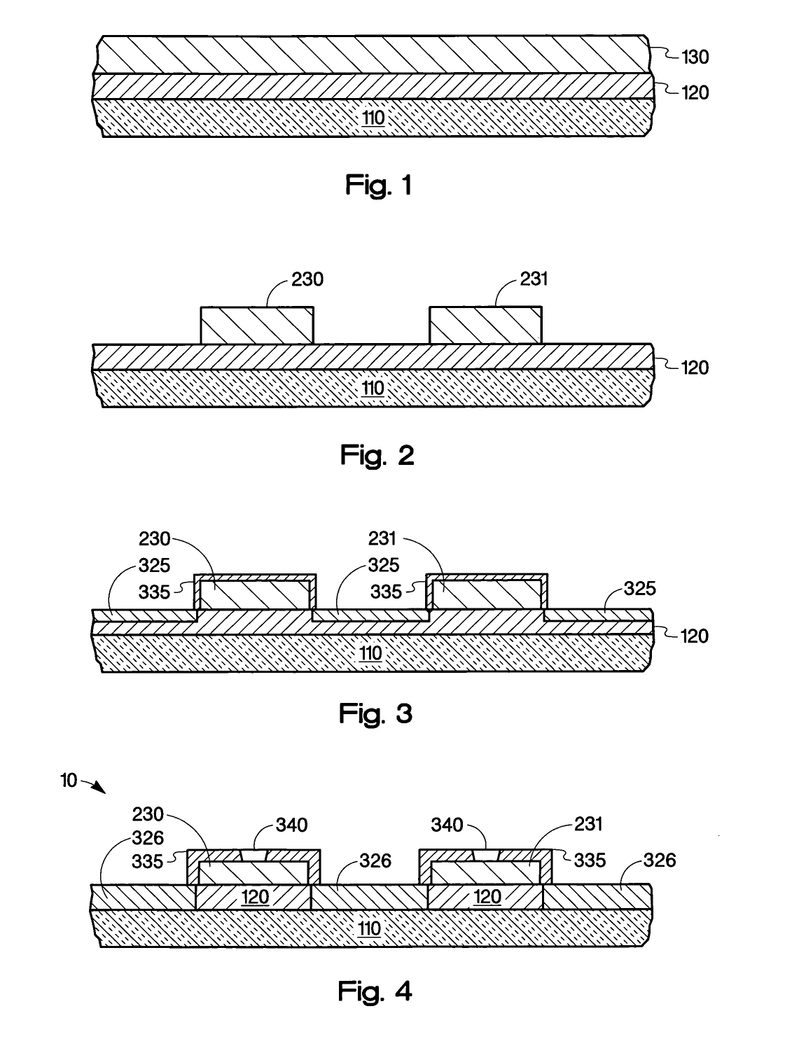

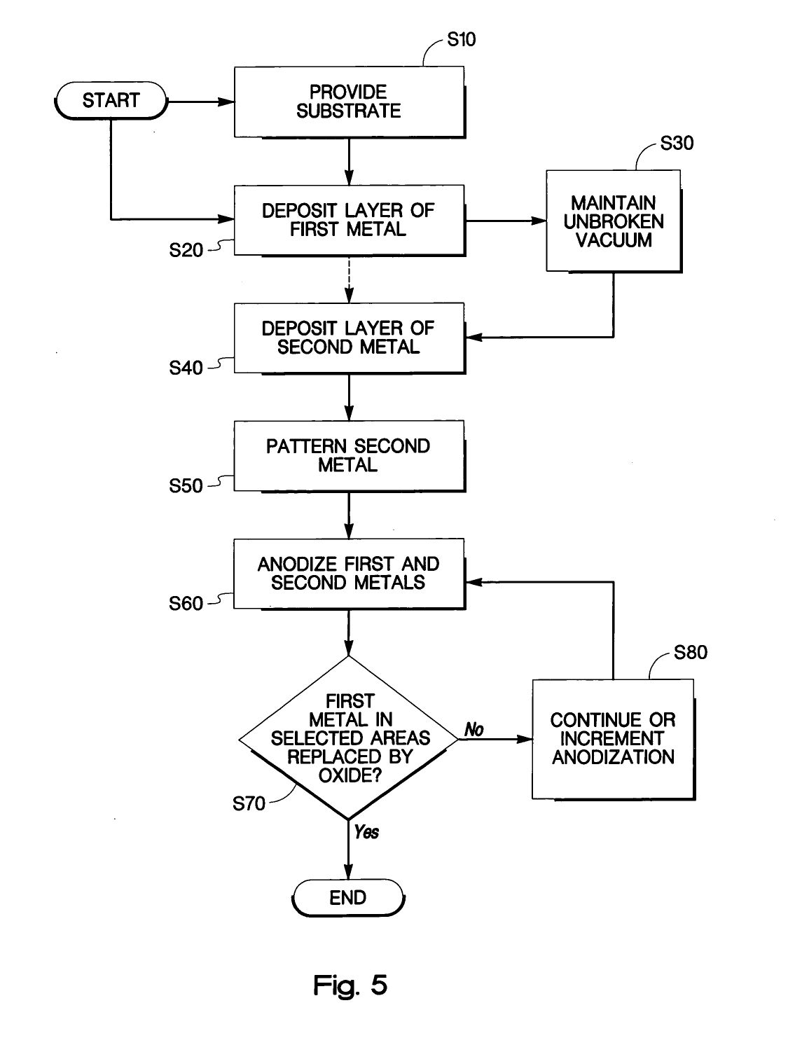

FIGS. 1-4 are cross-sectional side elevation views of embodiments of patterned metal structures at various stages of manufacture, and FIG. 5 is a flow chart schematically depicting an embodiment of a method using anodization in preparation of embodiments of patterned metal structures. Steps of the method are denoted in FIG. 5 by reference numerals S10, S20, . . . , S80, and arrows depict a sequence of the steps. A dashed arrow denotes an alternate path that may be followed under certain conditions.

If appropriate, a substrate 110 having a non-conductive surface is provided (step S10). In a vacuum environment, a layer 120 of a first metal is deposited (step S20) on substrate 110, as shown in FIG. 1, the first layer having a first predetermined thickness as described above. A layer 130 of a second metal is deposited (step S40) over the first metal 120 to a second predetermined thickness as described above.

If, as is often the case, the first metal layer would oxidize when exposed to air, the second metal layer deposition is done without breaking the vacuum, i.e., while maintaining the vacuum (step S30). This avoids the formation of a thin layer of “native oxide” on the first metal layer.

In other words, step S40 of depositing a layer of the second metal is performed after step S20 of depositing a layer of the first metal, without exposing the first metal to any oxidizing atmosphere and without exposing the first metal to any contaminants. Step S30 accomplishes this by not breaking the vacuum, since step S40 of depositing a layer of the second metal is performed in vacuum after step S20 of depositing a layer of the first metal is performed in vacuum without breaking the vacuum between steps S20 and S40.

In step S50, the second metal is patterned by removing the second metal from selected areas while leaving a continuous layer of the first metal, as shown in FIG. 2, where the remaining portions of the patterned second-deposited metal are denoted by reference numerals 230 and 231. Those skilled in the art will recognize that step S50 may be performed by any of a number of presently developed or future developed methods of patterning a metal film, e.g., by using photolithography, i.e., depositing and patterning a layer of photoresist over the second-deposited metal layer 130.

In such methods, removal of the second metal from the selected areas may be done using an etching process that removes the second-deposited metal in the selected areas but stops at the surface of the first-deposited metal, while leaving portions 230 and 231 un-etched because they are protected by photoresist. The etchant employed is said to have a high selectivity of the second (top) metal to the first (bottom) metal.

For example, if the first-deposited metal 120 is tantalum and the second-deposited metal 130 is aluminum, an etch solution of about 16:9:1:2 (phosphoric:nitric acid:acetic acid:water) may be used as an etchant in step S50 to remove the aluminum in the selected areas but effectively stop at the surface of the tantalum. The etchant employed has a substantially lower etch rate for the first-deposited metal than for the second-deposited metal, so the etchant in this example has a high selectivity of aluminum to tantalum. In this example, step S50 will form a sloped aluminum edge (not shown) and is selective to tantalum.

In step S60, the first and second metals are anodized as described above. As shown in FIG. 3, an oxide 325 of the first-deposited metal is formed on the selected areas of first metal layer 120, i.e., except where the first metal 120 is protected by the remaining portions 230 and 231 of second metal layer 130. An oxide 335 of the second-deposited metal is formed on the remaining portions 230 and 231 of second metal layer 130. As anodization proceeds, a portion of the first-deposited metal 120 is consumed by conversion to its oxide 325, and a portion of the second-deposited metal 130 is consumed by conversion to its oxide 335.

When the first thickness of the first metal in the selected areas is replaced by an oxide of the first metal (step S70) and the patterned second metal is covered by a layer of an oxide of the second metal, the anodization may be stopped. Otherwise (step S80), the anodization (S60) is continued until the first thickness of the first metal in the selected areas is replaced by an oxide of the first metal and the patterned second metal is covered by a layer of an oxide of the second metal. As described above, anodization of the two metals in step S60 is conveniently done simultaneously for embodiments such as those illustrated in FIGS. 1-5.

The final patterned metal structure 10 is shown in FIG. 4, where the first-deposited metal 120 is replaced by oxide in the selected areas, so that first-deposited-metal oxide 326 extends completely through the thickness of the first-deposited metal in those selected areas, down to the insulating surface of substrate 110. Thus, in this final patterned metal structure of FIG. 4, the oxide regions 326 also extend laterally between the remaining distinct elemental metal portions 230 and 231 of patterned second-deposited metal 130, thus insulating distinct elemental metal portions 230 and 231 from each other.

Instead of immersing an entire substrate in the anodizing bath, step S60 of anodizing the first and second metals may be performed incrementally by substeps in which selected portions of the substrate are successively immersed.

When the thicknesses of the deposited metal layers 120 and 130 are chosen according to the principles described above, the thickness of the second-deposited metal layer 130 is sufficient to leave a portion (230, 231) of the second metal in elemental metal form when the thickness of the first-deposited metal layer 120 under the selected areas is completely anodized, as shown in FIG. 4. In some embodiments, this may be achieved when the thickness of the first-deposited metal layer 120 is less than the thickness of the second-deposited metal layer 130.

The two anodizable metals used for layers 120 and 130 are chosen to be suitable for particular applications. For example, the first-deposited metal may comprise a metal such as one or more of tantalum, niobium, vanadium, tungsten, molybdenum, titanium, zirconium, hafnium, and their mixtures and alloys. The second-deposited metal may comprise a metal such as one or more of aluminum, gallium, indium, tin, thallium, and their mixtures and alloys, for example. As noted above, both anodizable metals anodize in the same anodization bath chemistry and at the same current/voltage conditions.

Also shown in FIG. 4 are via openings 340, selectively formed to extend through at least the oxide of the second metal if desired. Other via openings (not shown) may be selectively formed to extend through at least the first metal if desired.

A useful result of these methods is an embodiment of a patterned metal structure covered by oxide of the metal. The patterned metal is covered by oxide on its top surface as well as on its edges.

Thus, another embodiment of a patterned metal structure 10 is made by depositing a first thickness of a first metal on a substrate, depositing a second thickness of a second metal over the first metal, patterning the second metal by removing portions of the second metal from selected areas while leaving a continuous layer of the first metal, and anodizing the first and second metals until the first thickness of the first metal under the selected areas is replaced by an oxide of the first metal (except where the first metal is covered by the second metal), and until the patterned second metal is covered by a layer of an oxide of the second metal.

The resulting patterned metal structure 10 thus comprises a patterned layer of a first metal over a layer of a second metal on a substrate, the patterned layer of the first metal having an oxide of the first metal covering the first metal, an oxide of the second metal covering the substrate except where the second metal is covered by the first metal, and the oxides of the first and second metals having been formed by simultaneous anodization. The first-deposited metal and the second-deposited metal in embodiments of this patterned metal structure 10 may be characterized in that they are capable of being anodized in the same anodization bath chemistry and at the same current/voltage conditions. The anodization bath used may employ as an electrolyte a suitable concentration of an aqueous solution of an acid, such as phosphoric, citric, acetic, boric, tartaric, sulfuric, chromic, or oxalic acid, for example. The anodization bath used may also employ as an electrolyte a suitable concentration of a neutral solution such as ammonium borate or phosphate. As for other embodiments described above, anodization of the two metals is conveniently done substantially simultaneously, i.e., by anodizing the first metal and the second metal during at least partially overlapping time intervals.

FIGS. 6 and 7 are cross-sectional side elevation views of another embodiment of patterned metal structures at two stages of manufacture. In FIG. 6, the first-deposited (bottom) metal layer is only partially anodized in a first anodization step using a first anodization bath under first predetermined conditions (e.g., voltage, current, temperature, chemical composition, concentration, pH, anodization rates, and anodization time duration). The second-deposited metal portion 230 is anodized, forming oxide layer 335 as in embodiments described above with reference to FIGS. 1-5. At the stage shown in FIG. 6, the thickness of anodized first metal 325 does not extend downward all the way to substrate 110. FIG. 7 shows a result of performing a second anodization step, which may be performed in a second anodization bath under second predetermined conditions, which may differ from the first anodization bath and/or the conditions of the first anodization step. For example, the second anodization bath used in the second anodization step may have a chemical composition with a higher anodization rate for the first-deposited metal 120 than the anodization bath used in the first anodization step. In FIG. 7, anodization of the first-deposited metal 120 has proceeded beyond the depth shown by dashed line 327 where anodization had stopped (FIG. 6), extending further to a second depth and forming an oxide layer 326 except where the first-deposited metal has been protected from anodization by portions 230 of the second-deposited metal. As shown in FIG. 7, the second depth of oxide after the second anodization step may extend all the way to substrate 110 if desired.

FIGS. 8 and 9 are cross-sectional side elevation views of yet another embodiment of patterned metal structures at two stages of manufacture. As shown in FIG. 8, in a first anodization step using a first anodization bath under first predetermined conditions (e.g., voltage, current, temperature, chemical composition, concentration, pH, anodization rates, and anodization time duration), the second-deposited metal portion 230 is anodized, forming oxide layer 335 as in embodiments described above with reference to FIGS. 1-5, but the first-deposited (bottom) metal layer is not anodized.

In other words, the first anodization step may be performed under conditions in which only the second-deposited metal is anodized. FIG. 9 shows a result of performing a second anodization step, which may be performed in a second anodization bath under second predetermined conditions, which may differ from the first anodization bath and/or from the conditions of the first anodization step. As shown in FIG. 9, the second anodization step has formed an oxide layer 326 except where the first-deposited metal 120 has been protected from anodization by the portions of the second-deposited metal. Again, the oxide depth after the second anodization step may extend all the way to substrate 110 if desired, as shown in FIG. 9. The conditions of the first anodization step of FIG. 8 may include covering the first-deposited metal layer with a protective layer of sacrificial material such as photoresist (not shown) at least wherever the first-deposited metal is not covered by portions 230 of second-deposited metal, to prevent anodization of the first-deposited metal in the first anodization step. The protective layer may also cover the second-deposited metal 230 and its oxide 335, e.g., to prevent further anodization of the second-deposited metal 230, if desired. Such a protective resist layer, if used, is removed at least selectively from at least the first-deposited metal layer before performing the second anodization step shown in FIG. 9, thus allowing anodization of un-protected portions of first-deposited metal 120. The various methods illustrated by FIGS. 1-5, FIGS. 6 and 7, and FIGS. 8 and 9 may also be combined in various combinations for particular applications.

Thus an embodiment of a method may be employed including depositing a first layer of a first thickness of a first metal on a substrate, depositing a layer of a second thickness of a second metal over the first metal, patterning the second metal by removing the second metal from selected areas while leaving a continuous layer of the first metal, anodizing at least the second metal at least partially in a first anodization, and anodizing at least the first metal at least partially in a second anodization. The first anodization and the second anodization may differ from each other with respect to one or more of the anodization bath chemical composition, concentration, voltage, current, temperature, pH, anodization rates, or anodization time duration, or combinations of these. In some method embodiments, the first metal is not anodized while anodizing at least the second metal at least partially in the first anodization. This may be achieved, for example, by using a sacrificial layer of resist. In such embodiments, the first metal is covered by the sacrificial layer of resist while anodizing at least the second metal at least partially in a first anodization. The sacrificial layer of resist is at least selectively removed before the second anodization. Selective removal of the resist may be done by photolithography, for example. In some method embodiments, the second metal is not anodized while anodizing at least the first metal at least partially in the second anodization.

### EXAMPLES OF SPECIFIC EMBODIMENTS

The general method embodiments described above provide methods of anodizing a number of different patterned metal structures. This section describes an example of the anodizing method applied to a specific structure using tantalum and aluminum. The specific anodizing method used for this example includes steps of depositing a first layer of tantalum on a substrate, the first layer having a uniform first thickness, depositing a layer of aluminum to a uniform second thickness over the layer of tantalum, patterning the aluminum by removing aluminum portions from selected areas while leaving a continuous layer of tantalum, and anodizing the aluminum and tantalum until the tantalum is replaced by tantalum oxide except where aluminum was not removed and until the patterned aluminum is covered by a layer of aluminum oxide.

For such specific embodiments, after patterning the aluminum 130, the substrate 110 with the two metal films 120 and 130 (e.g., trace portions 230 and 231) is immersed in electrolyte such as citric acid solution (0.1% by weight). The tantalum is connected to the positive terminal of a power supply. A platinum or aluminum cathode is connected to the negative terminal of the power supply and is immersed in the electrolyte facing parallel to the metal films 120 and 130 (e.g., trace portions 230 and 231), which serve as an anode. A constant current is applied to the anodization cell. In this configuration, oxides form on the anode metals as electrons are lost across the electrolyte/electrode interface. As shown in FIG. 3, aluminum oxide (Al₂O₃) 335 grows on exposed surfaces of the aluminum traces 230 and 231 including their top surfaces and their sidewalls. Tantalum pentoxide (Ta₂O₅) 325 grows on the exposed tantalum surface remaining in the selected areas.

As the tantalum oxide 325 grows and consumes the tantalum layer 120, the voltage drop across the article becomes a factor that increasingly affects the anodization. This voltage drop or any substantial non-uniformity of thickness in the tantalum metal layer 120 (due to a non-uniform deposition process, for example) can lead to regions of thicker tantalum metal that become electrically isolated from the anode electrical contact. Such isolated regions can no longer take part in the anodization process and, in the case of “whole substrate” simultaneous anodization, this thicker tantalum layer can cover a significant portion of the substrate. One approach to address this issue is to incrementally anodize by immersing a small portion of the substrate at any given time, without immersing other portions of the substrate. Nearly complete anodization may be achieved by reducing the length of the resistive path, thus decreasing the voltage drop. Further advancement toward nearly complete anodization may be accomplished by further decreasing the incremental step size during anodization and by starting with a more uniform thickness tantalum film. The same considerations apply more generally when the two metals are not specifically tantalum and aluminum. Thus, as in the more general embodiments, the step of anodizing the aluminum and tantalum may be performed incrementally by substeps in which selected portions of the substrate are successively immersed.

Thus, another embodiment provides a patterned metal structure 10 comprising a patterned aluminum layer over a layer of tantalum on a substrate, the patterned aluminum layer having aluminum oxide covering the aluminum, tantalum oxide covering the substrate except where tantalum is covered by aluminum, and the oxides of aluminum and tantalum being formed by anodization. As described for other embodiments, the anodization of the two metals is conveniently done simultaneously and in the same anodization bath at the same current and voltage conditions. The methods illustrated by FIGS. 6 and 7 and by FIGS. 8 and 9 respectively may also be applied to the specific embodiments utilizing tantalum and aluminum.

### INDUSTRIAL APPLICABILITY

Patterned metal structures made in accordance with the embodiments are useful in electronic devices, such as semiconductor devices including thin-film-transistor (TFT) integrated circuits, and many other types of devices. They may also be used in non-electronic applications.

Although the foregoing has been a description and illustration of specific embodiments, various modifications thereof can be made by persons skilled in the art without departing from the scope and spirit of the subject matter defined by the following claims. For example, after anodizing the first and second metals until the first thickness of the first-deposited metal under the selected areas is replaced by an oxide of the first-deposited metal, the anodization may be continued further for a time if desired, while anodizing the second-deposited metal to provide, for example, a desired thickness of the second-deposited metal or of the oxide of the second-deposited metal. The methods described for two anodizable metals may be extended to three or more anodizable metals. Functionally equivalent materials may be substituted for specific materials described.

What is claimed is:

1. A method, comprising:
a) depositing a first layer of a first metal on a substrate, the first layer having a first thickness,
b) depositing a layer of a second metal to a second thickness over the first metal,
c) patterning the second metal by removing the second metal from selected areas while leaving a continuous layer of the first metal, and
d) anodizing the first and second metals until the first thickness of the first metal under the selected areas is at least substantially replaced by an oxide of the first metal and until the patterned second metal is covered by a layer of an oxide of the second metal.

2. The method of claim 1, wherein the anodizing of the first and second metals is done substantially simultaneously.

3. The method of claim 1, further comprising providing a substrate having a non-conductive surface.

4. The method of claim 1, wherein the anodization rate of the first metal differs from the anodization rate of the second metal.

5. The method of claim 1, wherein the second thickness is sufficient to leave a portion of the second metal in elemental metal form when the first thickness of the first metal under the selected areas is completely anodized.

6. The method of claim 1, wherein the first thickness is less than the second thickness.

7. The method of claim 1, wherein depositing a layer of the second metal is performed after depositing a layer of the first metal, without exposing the first metal to any oxidizing atmosphere and without exposing the first metal to any contaminants.

8. The method of claim 7, wherein depositing a layer of the second metal is performed in vacuum after depositing a layer of the first metal is performed in vacuum, without breaking the vacuum.

9. The method of claim 1, wherein the first metal is selected from metals comprising one or more of tantalum, niobium, vanadium, tungsten, molybdenum, titanium, zirconium, hafnium, or mixtures or alloys thereof.

10. The method of claim 1, wherein the second metal is selected from metals comprising one or more of aluminum, gallium, indium, tin, thallium, or mixtures or alloys thereof.

11. The method of claim 1, wherein patterning the second metal includes depositing and patterning a layer of photoresist over the second metal.

12. The method of claim 1, wherein patterning the second metal by removing the second metal from selected areas includes selectively etching the second metal, using an etchant having a substantially lower etch rate for the first metal than for the second metal.

13. The method of claim 12, wherein the first metal is tantalum, the second metal is aluminum, and the etchant is a solution comprising (phosphoric acid:nitric acid:acetic acid:water) in ratios 16:9:1:2 by volume.

14. The method of claim 1, further comprising selectively forming via openings extending through at least the first metal.

15. The method of claim 1, further comprising selectively forming via openings extending through at least the oxide of the second metal.

16. The method of claim 1, wherein anodizing the first and second metals is performed incrementally by substeps wherein selected portions of the substrate are successively immersed.

17. A patterned metal structure covered by oxide of the metal, made by the method of claim 1.

18. A patterned metal structure comprising a patterned layer of a first metal disposed over a layer of a second metal on a substrate, the patterned layer of the first metal having an oxide of the first metal covering the first metal, an oxide of the second metal covering the substrate except where the second metal is covered by the first metal, and the oxides of the first and second metals being formed by anodization.

19. A method, comprising:
a) depositing a first layer of tantalum on a substrate, the first layer having a substantially uniform first thickness,
b) depositing a layer of aluminum to a substantially uniform second thickness over the layer of tantalum,
c) patterning the aluminum by removing aluminum portions from selected areas while leaving a continuous layer of tantalum, and
d) anodizing the aluminum and tantalum until the tantalum is replaced by tantalum oxide except where aluminum was not removed and until the patterned aluminum is covered by a layer of aluminum oxide.

20. The method of claim 19, wherein anodizing the aluminum and tantalum is performed incrementally by substeps wherein selected portions of the substrate are successively immersed.

21. A structure comprising a patterned aluminum layer over a layer of tantalum on a substrate, the patterned aluminum layer having aluminum oxide covering the aluminum, tantalum oxide covering the substrate except where tantalum is covered by aluminum, and the oxides of aluminum and tantalum being formed by anodization.

22. A method, comprising:
a) depositing a first layer of a first metal on a substrate, the first layer having a first thickness,
b) depositing a layer of a second metal to a second thickness over the first metal,
c) patterning the second metal by removing the second metal from selected areas while leaving a continuous layer of the first metal,
d) anodizing at least the second metal at least partially in a first anodization, and
e) anodizing at least the first metal at least partially in a second anodization.

23. The method of claim 22, wherein the first anodization and the second anodization differ from each other with respect to one or more of the anodization bath chemical composition, concentration, voltage, current, temperature, pH, anodization rates, or anodization time duration, or combinations thereof.

24. The method of claim 22, wherein the first metal is not anodized while anodizing at least the second metal at least partially in a first anodization.

25. The method of claim 24, wherein the first metal is covered by a sacrificial layer of resist while anodizing at least the second metal at least partially in a first anodization and wherein the sacrificial layer of resist is at least selectively removed before the second anodization.

26. The method of claim 22, wherein the second metal is not anodized while anodizing at least the first metal at least partially in a second anodization.
